(19) United States
(12) Patent Application Publication
(10) Pub. No.: US 2015/0349221 A1
(43) Pub. Date: Dec. 3, 2015

(54) LIGHT-EMITTING DEVICE PACKAGE

(71) Applicant: BRIDGELUX, INC., Livermore, CA (US)

(72) Inventor: Vladimir ODNOBLYUDOV, Danville, CA (US)

(21) Appl. No.: 14/726,355

(22) Filed: May 29, 2015

Related U.S. Application Data
(60) Provisional application No. 62/005,898, filed on May 30, 2014.

(51) Int. Cl. H01L 33/60; H01L 33/62

(52) U.S. Cl. CPC H01L 33/60; H01L 33/62

(57) ABSTRACT

One aspect of a light-emitting apparatus is disclosed. The light-emitting apparatus may include a substrate having a reflective surface. The light emitting apparatus may include a reflector and conductor arranged with the surface of the substrate. The reflector has a higher reflectivity than the conductor and covers a substantially greater area of the surface than the conductor. The light emitting device may include a flip-chip LED arranged with the surface of the substrate and electrically coupled to the conductor.

### CLAIM OF BENEFIT TO PRIOR APPLICATIONS

This application claims the benefit of priority from U.S. Provisional Patent Application No. 62/005,898, entitled “LIGHT-EMITTING DEVICE PACKAGE,” filed on May 30, 2014, the contents of which are hereby incorporated by reference herein in their entirety.

### BACKGROUND

1. Field

The present disclosure relates generally to a chip on board light-emitting package and, more particularly, to a chip on board light emitting package having a flip-chip LED arranged on a highly reflective surface.

2. Background

Conventional chip on board light emitting packages often use lateral LEDs to achieve the best luminous efficacy and performance. This is because the structure of lateral LEDs permits arranging the lateral LEDs on highly reflective surfaces made of pure silver. The silver is typically fabricated by a Plasma Vapor Deposition (PVD) sputter technique, which produces a surface having a reflectivity of approximately 98%. However, the light extraction achieved from lateral LEDs may be compromised by the need for electrical connections such as metal contacts, bonding pads, and wire bonds on the LEDs and exposed portions of the reflective substrate. These metal contacts, bonding pads, and wire bonds can parasitically absorb light emitted from the LEDs and limit the amount of light output from the light emitting package.

Flip-chip LEDs are a viable substitute for lateral LEDs because flip-chip LEDs negate the need for the light absorbing metal contacts, bonding pads, and wire bonds on the LED and exposed portions of the substrate. However, use of flip-chip LEDs introduces other performance challenges. For instance, the architecture of a chip-on-board package utilizing a flip-chip LED typically requires arrangement over an electrically conductive layer such as plated silver. Plated silver has a reflectivity of around 92%, which is less than PVD silver. Even though the parasitic light absorbing elements are not used with the flip-chip configuration, the reflective qualities of the silver plating are less desirable than the greater reflective qualities of PVD silver. Therefore, it is difficult to configure a chip on board light emitting package with maximum reflectivity and minimal light absorption.

### SUMMARY

Several aspects of the present invention will be described more fully hereinafter with reference to various apparatuses.

One aspect of a light emitting apparatus is disclosed. The light-emitting apparatus may include a substrate having a reflective surface. The light emitting apparatus may include a reflector and conductor arranged with the surface of the substrate. The reflector has a higher reflectivity than the conductor and covers a greater area of the surface than the conductor. The light emitting apparatus may include a flip-chip LED arranged with the surface of the substrate and electrically coupled to the conductor.

Another aspect of a light emitting apparatus is disclosed. The light emitting apparatus may include a substrate having a surface. The light emitting apparatus may include a reflector arranged with the surface of the substrate. The reflector has at least 95% reflectivity. The light emitting apparatus may include a flip-chip LED arranged with the surface of the substrate.

Another aspect of a light emitting apparatus is disclosed. The light emitting apparatus may include a substrate having a surface. The light emitting apparatus may include a reflector arranged with the surface of the substrate. The light emitting apparatus may include a flip-chip LED arranged with the reflector. The flip-chip LED is electrically insulated from the reflector.

It is understood that other aspects of apparatuses will become readily apparent to those skilled in the art from the following detailed description, wherein various aspects of apparatuses and methods are shown and described by way of illustration. As understood by one of ordinary skill in the art, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatuses will now be presented in the detailed description by way of example, and not by way of limitation, with reference to the accompanying drawings, wherein:

FIG. 1 is a cross-section view of an exemplary embodiment of a light emitting package.

FIG. 2 is a cross-section view of an exemplary embodiment of a light emitting package that shows the composition of the package substrate.

FIG. 3a is a plan view of an exemplary embodiment of a light emitting package.

FIG. 3b is a cross-section view of the light emitting package of FIG. 3a.

FIG. 4 is a cross-section view of an exemplary embodiment of a light emitting package.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus, method or article of manufacture does not require that all embodiments of the invention include the described components, structure, features, functionality, processes, advantages, benefits, or modes of operation.

The various aspects of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus or method. Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “beneath” or “bottom” and “above” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being “above” other elements would then be oriented “below” other elements and vice versa. The term “above”, can therefore, encompass both an orientation of “above” and “below,” depending of the particular orientation of the apparatus. Similarly, if an apparatus in the drawing is turned over, elements described as “below” other elements would then be oriented “above” the other elements. The terms “below” can, therefore, encompass both an orientation of above and below.

It will be further understood that the terms “comprises” and/or “comprising,” when used in this specification, specify the presence of stated features, steps, operations, elements, and/or components, but do not preclude the presence or addition of one or more other features, integers, steps, operations, elements, components, and/or groups thereof. The term “and/or” includes any and all combinations of one or more of the associated listed items.

Unless otherwise defined, all terms (including technical and scientific terms) used herein have the same meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In the following detailed description, various aspects of the present invention will be presented in the context of a light-emitting device. However, those skilled in the art will realize that these aspects may be extended to other apparatus and/or their features, operations, elements, and/or components. Accordingly, any reference to a light-emitting device is intended only to illustrate the various aspects of the present invention, with the understanding that such aspects may have a wide range of applications.

The following description describes a chip on board light emitting package that is designed to maximize light output by utilizing highly reflective surface materials and minimizing the amount of less reflective material that covers the reflective surface. The light emitting package may utilize a light emitting diode (LED) architecture that provides optimal light emission patterns by leaving the top surface of the LED free of any bonding pads or wires. Such LEDs may be flip-chip LEDs, which will be described in greater detail in the following paragraphs, arranged on a highly reflective surface.

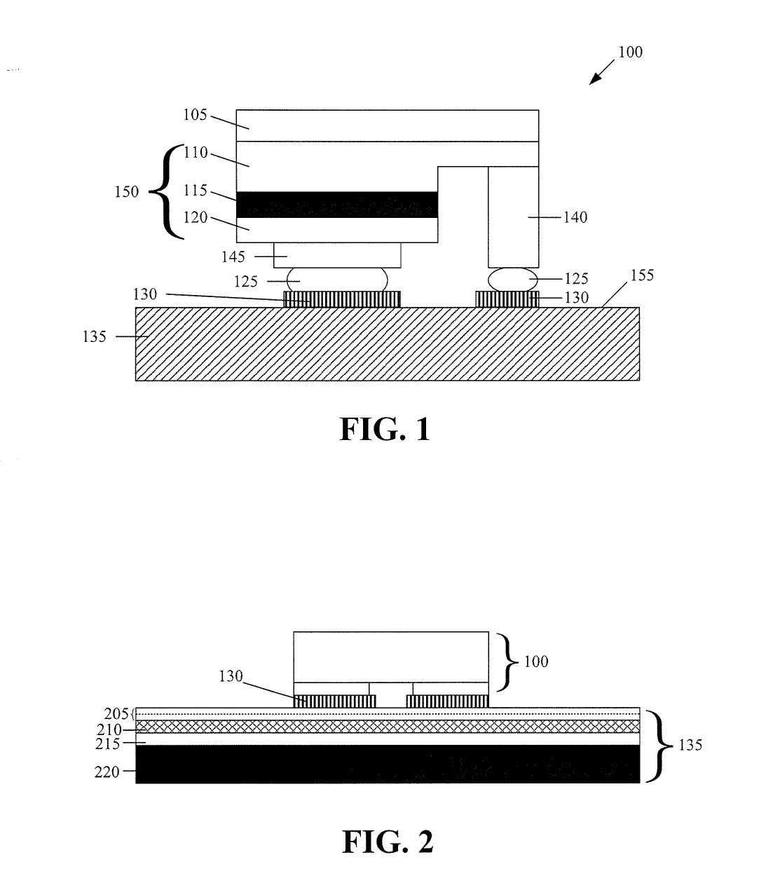

FIG. 1 is a cross-section view of an exemplary embodiment of a light emitting package. The light emitting package includes an LED 100, a substrate 135, a top surface 155 of the substrate 135, and a conductive layer 130. The LED 100 may be an LED in a flip-chip configuration (flip-chip LED). A flip-chip configuration refers to flipping the LED chip upside down such that light may be emitted through a transparent growth substrate on top. Such transparent substrates may include sapphire (Al₂O₃), silicon, and other insulating material.

As shown in FIG. 1, the flip-chip LED 100 includes a substrate 105, such as the transparent growth substrate described in the preceding. The LED 100 also includes an epitaxial-layer structure 150, a pair of electrodes 140 and 145, and solders 125. The epitaxial-layer structure 150 comprises an active region 115 and two oppositely doped epitaxial regions 110 and 120. In this example, the epitaxial region 110 is an n-type semiconductor region and the epitaxial region 120 is a p-type semiconductor region, however, in some aspects of the light emitting package, the regions may be reversed.

As will be discussed in greater detail below, flip-chip bonding an LED to a substrate allows light to be extracted from the transparent growth substrate without blockages such as bonding wires and bonding pads. For instance, the flip-chip LED 100, as shown in FIG. 1, is arranged epitaxial-layers-down on the substrate 135. The n-type semiconductor region 110 is deposited on the substrate 105. The active region 115 is formed on the n-type semiconductor region 110, and the p-type semiconductor region 120 is formed on the active region 115. A portion of the p-type semiconductor region 120, the active region 115, and the n-type semiconductor region 110 is etched away to expose a portion of the n-type semiconductor region 110. The etch allows the electrode 145 to be connected to the p-type semiconductor region 120, electrically isolated from the n-type semiconductor region 110. The electrode 140 connects to the n-type semiconductor region. As those skilled in the art will readily appreciate, the various concepts described throughout this disclosure may be extended to any suitable epitaxial-layer structure. Additional layers (not shown) may also be included in the epitaxial-layer structure 150, including but not limited to buffer, nucleation, contact and current spreading layers as well as light extraction layers.

As shown in FIG. 1, the solders 125 electrically couple the flip-chip LED 100 to the conductive layer 130, which is arranged over the substrate 135. The substrate 135 will be described in greater detail with respect to FIG. 2. The conductive layer 130 includes narrow wire traces. In one aspect of the light emitting package, the wire traces on conductive layer 130 cover less than 5% of the top surface 155 of the substrate 135. This configuration leaves the majority of the surface 155 of the substrate 135 exposed. The substrate 135 may include multiple layers of material used to increase the reflectivity of the surface 155 of the substrate 135. Therefore, exposing a greater area of the top surface 155 of the substrate 135 will maximize total light output from the light emitting package.

FIG. 2 is a cross-section view of an exemplary embodiment of a light emitting package that shows the composition of the package substrate. The light emitting package includes the LED 100 and the conductive layer 130, which was described in detail with respect to FIG. 1. The light emitting package also includes a more detailed view of the substrate 135.

As shown, the substrate 135 includes an aluminum substrate 220, an anodized aluminum layer 215 arranged above the aluminum substrate 220, and a silver layer 210 arranged above the anodized aluminum layer 215. Some aspects of the light emitting package may also include at least one dielectric layer below the silver layer. In an exemplary configuration, the silver layer 210 may be disposed on the anodized aluminum layer 215 using plasma vapor deposition (PVD). The anodized aluminum of the anodized aluminum layer 215 is more rigid than the aluminum substrate 220 and protects the aluminum substrate 220.

As further illustrated by FIG. 2, a Distributed Bragg Reflector (DBR) 205 is arranged over the PVD silver layer 210. The DBR 205 may include two reflective layers as indicated by the dashed line through the DBR 205. In some aspects of the light emitting package, the reflective pair of layers may include aluminum oxide (Al₂O₃) and titanium dioxide (TiO₂). In other aspects of the light emitting package, the reflective pair of layers may include TiO₂ and silicon dioxide (SiO₂). Moreover, in an exemplary configuration, the DBR 205 may include multiple layers of semiconductor materials (e.g., Al2O3/TiO2 or TiO2/SiO2) with different refractive indices. A larger number of layers are required to achieve high reflectivity if the difference in refractive indices between the layers is small. As a result, the number of layers and composition of the DBR 205 may be selected to provide a predetermined reflectivity index.

In some aspects of the light emitting package, the PVD silver layer 210 provides a reflective index of greater than 95% because the PVD process yields a pure silver layer. Plated silver yields a reflectivity index of less than 93%. Therefore, the PVD silver layer 210 is more reflective than a plated silver layer. Additionally, the DBR 205 provides several functions when arranged over the PVD silver layer 210 aside from reflecting more light. For instance, the DBR 205 protects the PVD silver layer 210 and provides electrical isolation from the conductive layer 130. The PVD silver/DBR configuration ultimately provides for an increase in light output, especially when combined with a flip-chip LED configuration.

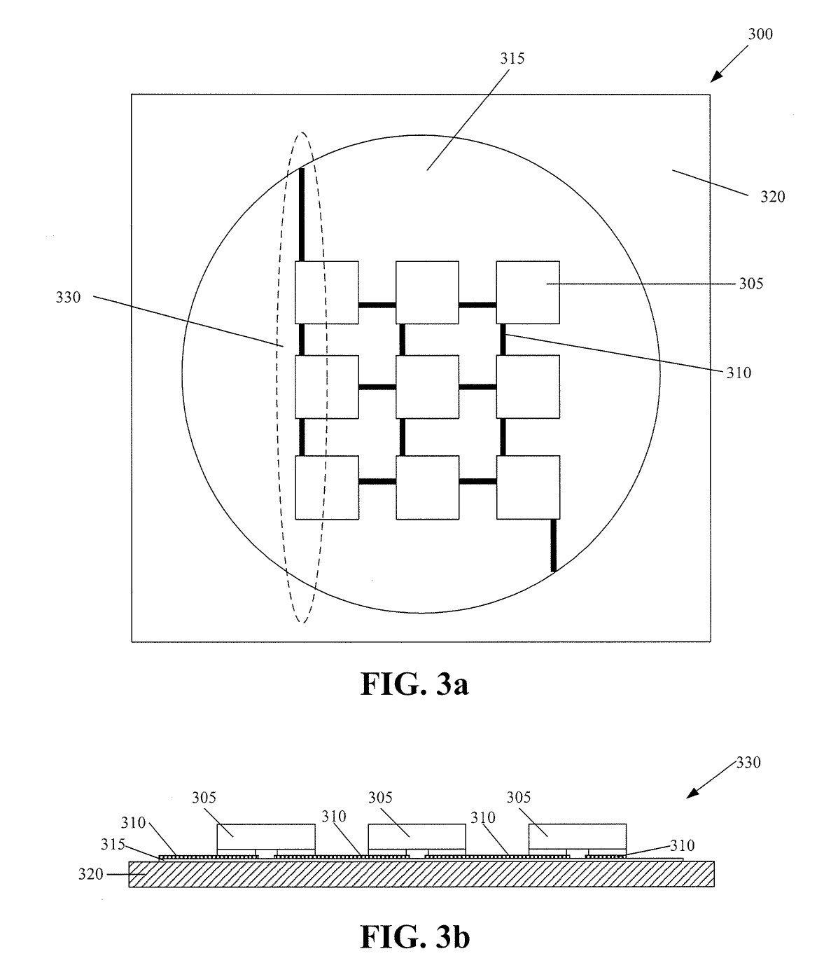

FIG. 3a is a plan view of an exemplary embodiment of a light emitting package 300. Some aspects of the light emitting package include an array of LEDs. As shown in FIG. 3a, the light emitting package includes an array of LEDs 305, conductive traces 310, reflective layer 315, and aluminum substrate 320. The LEDs 305 make up an array of LEDs that are electrically coupled by a web of conductive traces 310. The conductive traces may be made of laminated copper, or nickel-gold plating.

As shown, the LEDs 305 and the conductive traces 310 are arranged over the reflective layer 315. The reflective layer 315 may include PVD silver and a DBR. As discussed in the preceding section, the reflective layer 315 has greater reflectivity than the conductive traces 310. Therefore, as shown in FIG. 3a, the area of the reflective layer 315 that is covered by the conductive traces is kept to a minimum in order to maximize reflectivity within the light emitting package. For example, the conductive traces 310 may be arranged beneath the LED 305, covering only the area of the reflective layer 315 that is already covered by the LED 305. The conductive traces 310 may also use a narrow design between LEDs further limiting the area of the reflective layer 315 that is covered by less reflective material. In such examples, the conductive traces 310 may cover less than 5% of the reflective layer 315.

By minimizing the surface area of the conductive traces 310, greater light reflection from the reflective layer 315 may be realized. Moreover, greater luminous efficacy and performance can be achieved with this package design. The architecture described above maximizes light output by using the high reflectivity of the PVD silver/DBR combination in the reflective layer and a flip-chip LED configuration.

The reflective layer 315 is arranged over the aluminum substrate 320. As described, with respect to FIG. 2, the aluminum substrate may include anodized aluminum disposed over the aluminum substrate. The anodized aluminum is rigid and designed to protect the aluminum substrate.

FIG. 3a illustrates one exemplary arrangement for a light emitting package. However, several different arrangements may be used. Such arrangements may include more or less LEDs, varying placements of the LEDs on the reflective layer, and different positioning of the conductive traces. Such configurations are possible while still maintaining the integrity of the highly reflective surface and highly efficient light output. Furthermore, the architecture described above may be manufactured using reel-to-reel-base material manufacturing, which provides for better thermal dissipation than traditional architectures.

FIG. 3b is a cross-section view of the light emitting package of FIG. 3a. As shown, side view 330 includes the array of flip-chip LEDs 305 arranged over the conductive traces 310. The conductive traces 310 are shown below the LEDs and electrically couple the LEDs by the p and n electrodes. The conductive traces 310 are arranged over the reflective layer 315. The reflective layer 315 is arranged over the aluminum substrate 320.

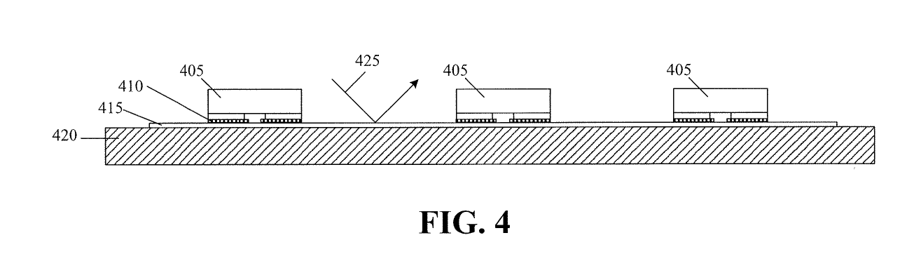

FIG. 4 is a cross-section view of an exemplary embodiment of a light emitting package. In this exemplary embodiment of the light emitting package, light output is maximized by utilizing flip-chip LEDs, a highly reflective surface, and narrow conductive traces that cover a minimal area of the highly reflective surface.

As shown, the light emitting package includes LEDs 405, conductive traces 410, a reflective surface 415, and an aluminum substrate 420. Light may reflect off of the reflective surface in a pattern similar to reflective pattern 425. FIG. 4 is similar to FIG. 3b. However, FIG. 4 better illustrates that the conductive traces 410 cover a minimal amount of the reflective layer 415. Specifically, as shown in this cross-section view, the conductive traces only cover the portion of the reflective layer 415 that is already covered by the LEDs 405. Therefore, reflectivity is maximized by covering a minimal amount of the reflective layer 415 with the less reflective conductive traces 410.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A light emitting apparatus comprising:
a substrate having a surface;
a reflector and conductor arranged with the surface of the substrate, wherein the reflector has a higher reflectivity than the conductor and covers a greater area of the surface than the conductor; and
a flip-chip LED arranged with the surface of the substrate and electrically coupled to the conductor.

2. The light emitting apparatus of claim 1, wherein the reflector comprises Plasma Vapor Deposited (PVD) silver.

3. The light emitting apparatus of claim 2, wherein the reflector further comprises a Distributed Bragg Reflector (DBR), wherein the PVD silver is between the DBR and the substrate.

4. The light emitting apparatus of claim 3, wherein the DBR comprises at least one pair of aluminum oxide and titanium dioxide layers.

5. The light emitting apparatus of claim 4, wherein the number of layer pairs corresponds to the reflectivity for the reflector.

6. The light emitting apparatus of claim 3, wherein the DBR comprises at least one pair of titanium dioxide and silicon dioxide layers.

7. The light emitting apparatus of claim 5, wherein the number of layer pairs corresponds to the reflectivity for the reflector.

8. The light emitting apparatus of claim 1, wherein the substrate comprises an aluminum layer and an anodized aluminum layer, wherein the anodized aluminum layer is between the aluminum substrate and the reflector.

9. The light emitting apparatus of claim 1, wherein the reflector covers at least 95% of the surface of the substrate.

10. A light emitting apparatus comprising:
a substrate having a surface;
a reflector arranged with the surface of the substrate, the reflector having at least 95% reflectivity; and
a flip-chip LED arranged with the surface of the substrate.

11. The light emitting apparatus of claim 10, wherein the reflector comprises Plasma Vapor Deposited (PVD) silver.

12. The light emitting apparatus of claim 11, wherein the reflector further comprises a Distributed Bragg Reflector (DBR), wherein the PVD silver is between the DBR and the substrate.

13. The light emitting apparatus of claim 12, wherein the DBR comprises at least one pair of aluminum oxide and titanium dioxide layers.

14. The light emitting apparatus of claim 12, wherein the DBR comprises at least one pair of layers comprising titanium dioxide and silicon dioxide.

15. The light emitting apparatus of claim 10, wherein the substrate comprises an aluminum layer and an anodized aluminum layer, wherein the anodized aluminum layer is between the aluminum substrate and the reflector.

16. The light emitting apparatus of claim 10, further comprising a conductor arranged with the surface of the substrate, the flip-chip LED being electrically coupled to the conductor.

17. The light emitting apparatus of claim 16, wherein the conductor covers less than 5% of the surface of the substrate.

18. The light emitting apparatus of claim 17, wherein the conductor comprises at least one of laminated copper and nickel-gold plating.

19. A light emitting apparatus comprising:
a substrate having a surface;
a reflector arranged with the surface of the substrate; and
a flip-chip LED arranged with the reflector, wherein the flip-chip LED is electrically insulated from the reflector.

20. The light emitting apparatus of claim 19, further comprising a conductor arranged with the surface of the substrate, the flip-chip LED being electrically coupled to the conductor.

21. The light emitting apparatus of claim 20, wherein the conductor comprises at least one of laminated copper and nickel-gold plating.

22. The light emitting apparatus of claim 19, wherein the conductor covers less than 5% of the surface of the substrate.

23. The light emitting apparatus of claim 19, the reflector comprises Plasma Vapor Deposited (PVD) silver.

24. The light emitting apparatus of claim 23, wherein the reflector further comprises a Distributed Bragg Reflector (DBR), wherein the PVD silver is between the DBR and the substrate.

25. The light emitting apparatus of claim 24, wherein the DBR comprises at least one pair of aluminum oxide and titanium dioxide layers.

26. The light emitting apparatus of claim 24, wherein the DBR comprises at least one pair of titanium dioxide and silicon dioxide layers.

27. The light emitting apparatus of claim 19, wherein the substrate comprises an aluminum layer and an anodized aluminum layer, wherein the anodized aluminum layer is between the aluminum substrate and the reflector.
